(19) United States
(12) Patent Application Publication
(10) Pub. No.: US 2025/0142899 A1
(43) Pub. Date: May 1, 2025

(54) POWER SEMICONDUCTOR DEVICE AND ASSOCIATED METHODS

(71) Applicant: NEXPERIA B.V, Nijmegen (NL)

(72) Inventors: Jianglong Yin, Shanghai (CN); Mengqi Yang, Shanghai (CN); Fan Chen, Shanghai (CN); Yanming Chen, Shanghai (CN)

(73) Assignee: NEXPERIA B.V., Nijmegen (NL)

(21) Appl. No.: 18/930,581

(22) Filed: Oct. 29, 2024

(30) Foreign Application Priority Data
Oct. 30, 2023 (CN) 202311433891.5

(51) Int. Cl. H01L 29/06; H01L 21/266; H01L 29/66; H01L 29/78

(52) U.S. Cl. CPC H10D 62/111; H01L 21/266; H10D 30/0291; H10D 30/66

(57) ABSTRACT

A semiconductor power device includes an active region that has a drift region of a first conductivity type and a body region of a second, opposite conductivity type. A super junction region is arranged at least partially between the drift region and the body region. The super junction region has a first pillar of the first conductivity type and at least a portion of a second pillar of the second conductivity type. The first pillar is arranged adjacent to the portion of the second pillar. At least one of: a doping concentration of the first pillar is constant and a doping concentration of the portion of the second pillar decreases, or the doping concentration of the first pillar increases and the doping concentration of the portion of the second pillar is constant.

### CROSS-REFERENCE TO RELATED APPLICATIONS

This application claims priority under 35 U.S.C. § 119 to Chinese patent application 202311433891.5, filed Oct. 30, 2024, the entire disclosure of which is incorporated herein by reference.

### BACKGROUND OF THE DISCLOSURE

### 1. Field of the Disclosure

The present disclosure relates to a power semiconductor device and a method of manufacturing a power semiconductor device. Particularly but not exclusively, the present disclosure relates to a super junction (SJ) metal-oxide semiconductor field-effect transistor (MOSFET).

### 2. Description of Related Art

Power semiconductor devices such as metal-oxide semiconductor field-effect transistors (MOSFETs) or insulated-gate bipolar transistors (IGBTs) require a high breakdown voltage. It is possible to achieve a high value of breakdown voltage in the active regions of super junction MOSFETS, for example by using a number of thin semiconductor layers in the super junction area to create charge balance. However, it can be difficult to improve the Figure of Merit (FOM), which corresponds to a ratio of the breakdown voltage over the specific resistance of a super junction MOSFET, when a cell pitch is decreased. For example, when the cell pitch is decreased, a doping concentration in the super junction region of the MOSFET can be increased to decrease the specific resistance. However, this can also lead to a decrease of the breakdown voltage, which can be due to an increased electric field at a top portion of the super junction region compared to an electric field at a bottom portion of the super junction region.

U.S. Pat. No. 9,595,596 B2 relates to a power device, U.S. Pat. No. 9,024,381 B2 relates to a semiconductor device, U.S. Pat. No. 6,630,698B1 relates to a high-voltage semiconductor component and U.S. Pat. No. 8,283,720 B2 relates to power semiconductor device.

### SUMMARY OF THE DISCLOSURE

Aspects and preferred features are set out in the accompanying claims.

According to a first aspect of the present disclosure, there is provided a semiconductor power device comprising an active region, the active region comprising:
a drift region of a first conductivity type;
a body region of a second conductivity type, wherein the second conductivity type is opposite to the first conductivity type;
a super junction region arranged at least partially between the drift region and the body region, the super junction region comprising:
   a first pillar of the first conductivity type,
   at least a portion of a second pillar of the second conductivity type, the first pillar being arranged adjacent to the portion of the second pillar, wherein at least one of:
   a doping concentration of the first pillar is constant in a direction along the first pillar from the drift region to the body region and a doping concentration of the portion of the second pillar decreases in a direction along the portion of the second pillar from the drift region to the body region; or
   the doping concentration of the first pillar increases in the direction along the first pillar from the drift region to the body region and the doping concentration of the portion of the second pillar is constant in the direction along the portion of the second pillar from the drift region to the body region.

By configuring a doping concentration of the first pillar to be constant in a direction along the first pillar from the drift region to the body region and a doping concentration of the portion of the second pillar to decrease in a direction along the portion of the second pillar from the drift region to the body region, or the doping concentration of the first pillar to increase in the direction along the first pillar from the drift region to the body region and the doping concentration of the portion of the second pillar to be constant in the direction along the portion of the second pillar from the drift region to the body region, a breakdown voltage of the device can be increased. This in turn can lead to an increase in a ratio of the breakdown voltage over a specific resistance of the device. This ratio can also be referred to the Figure of Merit (FOM).

Additionally, an electric field at a top or a surface of the active region can be decreased. This can lead to a more even distribution of the electric field in the active region of the device. The effect of decreasing of the electric field at the top or surface of the active region can also be referred to as Reduced Surface Field (RESURF).

Additionally, an impact ionization location of the device can be located at a bottom of the super junction region, e.g. proximal to the drift region. This can result in an improved non-latch-up performance of the device. The improved latch-up performance can in turn result in a more even distribution of heat generated in the device.

The doping concentration of the portion of the second pillar can decrease linearly in the direction along the portion of the second pillar from the drift region to the body region. Alternatively, the doping concentration of the first pillar can increase linearly in the direction along the first pillar from the drift region to the body region.

The doping concentration of the portion of the second pillar can decrease stepwise in the direction along the portion of the second pillar from the drift region to the body region. Alternatively, the doping concentration of the first pillar can increase stepwise in the direction along the first pillar from the drift region to the body region.

The doping concentration of the portion of the second pillar can decrease in two or more steps. Alternatively, the doping concentration of the first pillar can increase in two or more steps.

The doping concentration of the first pillar at or near the body region can be larger, smaller, or the same as the doping concentration of the portion of the second pillar at or near the body region.

The super junction region can comprises a plurality of first pillars and a plurality of second pillars. The plurality of first pillars and the plurality of second pillars can be alternately arranged with each other. The portion of the second pillar can be part of or comprised in at least one second pillar of the plurality of second pillars. Each of the plurality of first pillars can arranged adjacent at least one of the plurality of second pillars. Each of the plurality of first pillars can form a p-n-junction with the at least one of the plurality of second pillars.

The semiconductor device can comprise a metal-oxide-semiconductor field-effect transistor (MOSFET) or an insulated-gate bipolar transistor (IGBT).

The first pillar or each of the plurality of first pillars can comprise or define a further drift region. The portion of the second pillar, the second pillar or each of the plurality of second pillars can comprise or define a partition region.

According to a second aspect of the present disclosure a method of manufacturing an active region of a semiconductor power device is provided. The method comprises forming a drift region of a first conductivity type on a substrate; and forming a super junction region on the drift region. The super junction region comprises: a first pillar of the first conductivity type, and at least a portion of a second pillar of the second conductivity type. The first pillar is arranged adjacent to the portion of the second pillar. At least one of: a doping concentration of the first pillar is constant in a direction along the first pillar from the drift region to the body region and a doping concentration of the portion of the second pillar decreases in a direction along the portion of the second pillar from the drift region to the body region; or the doping concentration of the first pillar increases in the direction along the first pillar from the drift region to the body region and the doping concentration of the portion of the second pillar is constant in the direction along the portion of the second pillar from the drift region to the body region. The method further comprises forming a body region of a second conductivity type on at least a part of the super junction region.

Forming the super junction region can comprise performing each of steps (i) to (v) one or more times:
(i) depositing a semiconductor layer on or over the drift region;
(ii) forming a first mask on the semiconductor layer, the first mask exposing an upper surface of a first region of the semiconductor layer;
(iii) selectively doping the first region of the semiconductor layer to form a first region of a first conductivity type;
(iv) forming a second mask on the semiconductor layer, the second mask exposing an upper surface of a second region of the semiconductor layer, the second region of the semiconductor layer being laterally spaced from the first region of the semiconductor layer; and
(v) selectively doping the second region of the semiconductor layer to form a second region of a second conductivity type.

In a first iteration, the semiconductor layer can be deposited on the drift region. In one or more subsequent iterations, a subsequent semiconductor layer can be deposited on a previously deposited semiconductor layer.

When at least one subsequent iteration has been performed, a doping concentration of each first region of the first conductivity type can be the same. When at least one subsequent iteration has been performed, a doping concentration of a second region of the second conductivity type formed in the at least one subsequent iteration can be decreased relative to a doping concentration of a second region of the second conductivity type formed in a previous iteration.

When at least one subsequent iteration has been performed, a doping concentration of each second region of the second conductivity type can be the same. When at least one subsequent iteration has been performed, a doping concentration of a first region of the first conductivity type formed in the at least one subsequent iteration can be increased relative to a doping concentration of a first region of the first conductivity type formed in a previous iteration.

The method can comprise using a diffusion or redistribution process to form the first pillar and at least the portion of the second pillar.

Forming the super junction region can comprise forming a trench in a semiconductor region of a first conductivity type. The method can comprise forming the body region prior to forming the trench. The trench can be formed so that the trench extends through the body region into semiconductor region. The trench can extend into the semiconductor region in a vertical direction. The trench can be formed so that the trench is in contact with the body region. The trench can be formed so that the trench is in contact with the drift region.

A portion of the semiconductor region that is located adjacent to the trench can form the first pillar. Forming the super junction region can comprise filling the trench with a semiconductor material of a second conductivity type to form at least the portion of the second pillar.

According to a third aspect of the present disclosure there is provided a method of manufacturing a semiconductor power device comprising manufacturing an active region of the semiconductor power device according to the second aspect.

The device and method of manufacture of the present disclosure has one or more of the following advantages over state-of-the-art devices:
The device can have an increased breakdown voltage and increased Figure of Merit;
A distribution of an electric field in the active region can be improved;
The Reduced Surface Field (RESURF) effect can be improved;
A non-latch-up performance of the device can be improved;
A distribution of heat generated in the active region of the device can be more even; and
The manufacturing steps can be compatible with existing MOSFET and/or IGBT manufacturing processes and/or can be performed using materials and processing equipment commonly available in MOSFET and/or IGBT fabs.

### BRIEF DESCRIPTION OF THE DRAWINGS

Some embodiments of the disclosure will now be described, by way of example only and with reference to the accompanying drawings.

FIG. 1 shows schematically a cross-section of an active region of a semiconductor device.

FIG. 2 shows schematically a cross-section of a half of a unit cell of the device of FIG. 1.

FIGS. 3A to 3F show schematically different exemplary distributions of dopant dosages that can be used to form a first pillar and a second pillar of the device of FIGS. 1 and 2.

FIG. 4 shows an active charge carrier concentration in an exemplary semiconductor power device that has been simulated using the distribution of the n-type dopant and p-type dopant implantation dosages of FIG. 3A.

FIG. 5 shows a graph of drain source current curves over a breakdown voltage that have been simulated for each of the n-type dopant and p-type dopant implantation dosage distributions of FIG. 3A to 3F.

FIG. 6 shows a graph of electric field curves over a distance between a drain contact and a source contact of the device of FIGS. 1 and 2 that have been simulated for each of the n-type dopant and p-type dopant implantation dosage distributions of FIG. 3A to 3F.

FIG. 7 shows a comparison between the breakdown voltage, specific resistance and Figure of Merit that has been simulated for each of the n-type dopant and p-type dopant implantation dosage distributions of FIGS. 3A to 3F.

FIGS. 8A to 8F show simulations of impact ionization locations that have been simulated for each of the n-type dopant and p-type dopant implantation dosage distributions of FIGS. 3A to 3F.

FIGS. 9A to 9F show exemplary n-type dopant and p-type dopant concentrations of the first and second pillars, respectively, of the device of FIGS. 1 and 2 according to embodiments of the present disclosure.

FIGS. 10A to 10F show exemplary n-type dopant and p-type dopant concentrations of the first and second pillars, respectively, of the device of FIGS. 1 and 2 according to embodiments of the present disclosure.

FIGS. 11A to 11F shows steps of a method of manufacturing an active region of a semiconductor power device according to an embodiment of the disclosure.

FIGS. 12A to 12K shows steps of another method of manufacturing an active region of a semiconductor power device according to an embodiment of the disclosure.

FIG. 13 shows schematically a cross-section of a super junction region that has been formed using one or more steps of the method of FIGS. 12A to 12K.

### DETAILED DESCRIPTION OF THE DISCLOSURE

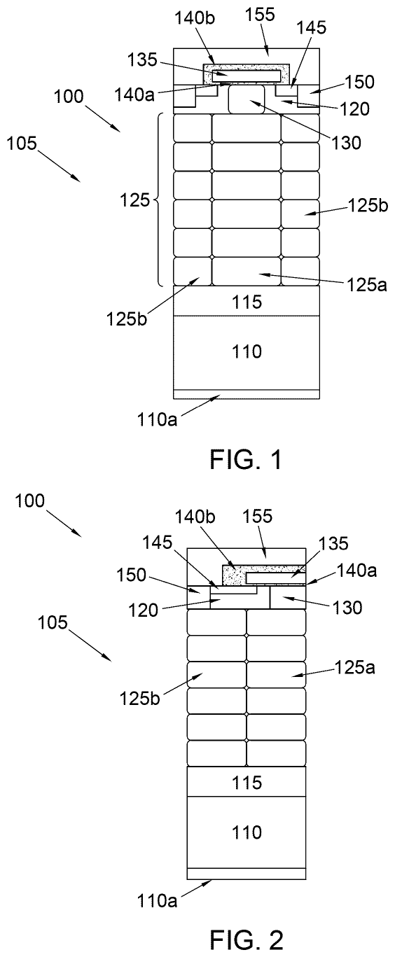

FIGS. 1 and 2 show schematically a cross-section of an active region 105 of a semiconductor device 100. The active region 105 shown in FIG. 1 can be considered as a unit cell, which can be repeated thousands of times in the device 100. The active region 105 shown in FIG. 2 can be considered as a half of the unit cell shown in FIG. 1. In the examples described herein, the device 100 is a silicon based super junction MOSFET. However, it will be appreciated that the device can comprise one or more alternative semiconductor materials. For example, the device can alternatively be silicon carbide (SiC) or Gallium Nitride (GaN) based.

The active region 105 comprises a substrate 110 of a first conductivity type. The substrate 110 can comprise an n-type doped semiconductor material, such as n+ silicon. An n-type dopant concentration of the substrate 110 can be larger than about 5×10¹⁸ cm⁻³. The substrate 110 is conductive and acts as a drain region. A thickness of the substrate can be between about 40 μm and about 100 μm.

The active region 105 comprises a drift region 115 arranged on the substrate 110. The drift region 115 comprises an n-type doped semiconductor material, such as n-type doped silicon. An n-type dopant concentration of the drift region 115 can be between about 5×10¹⁴ cm⁻³ and 5×10¹⁷ cm 3, such as about 7×10¹⁵ cm 3. The drift region 115 can also be referred to as an n-drift region, n-type buffer region or n-type voltage sustaining region. The drift region 115 is formed on or over the semiconductor substrate 110. In this embodiment, the drift region 115 comprises one or more epitaxial layers and has a thickness of about 15 μm. However, it will be appreciated that in other embodiments, the drift region can have a thickness that is more or less than 15 μm.

A drain contact 110a can be arranged on an underside of the substrate 110, e.g. a side of the substrate 110 that is opposite to the drift region 110. The drain contact 110a can comprise a conductive material, such as a metal material. The metal material can comprise a metal alloy, such as titanium nickel silver or another metal alloy.

The active area 105 includes a body region 120 of a second conductivity type. The second conductivity type is opposite to the first conductivity type. In the embodiment shown in FIGS. 1 and 2, the body region 120 comprises a p-type semiconductor material.

The active area 105 includes a super junction region 125. The super junction region 125 is arranged between the drift region 115 and the body region 120. The super junction region 125 comprises a plurality of first pillars 125a of the first conductivity type and a plurality of second pillars 125b of the second conductivity type. In this embodiment, each first pillar 125a is an n-type pillar and each second pillar 125b is a p-type pillar. The first pillars 125a can define further drift regions. The second pillars 125b can define partition regions. The first and second pillars 125a, 125b are alternately arranged and in contact with each other. For example, each first pillar 125a is arranged between two adjacent second pillars 125b. For example, in the unit cell shown in FIG. 1, the super junction region 125 comprises a first pillar 125a and two portions of two respective second pillars 125b. The first pillar 125a is arranged between the two portions the second pillars 125b. In the half of the unit cell shown FIG. 2, the super junction region comprises a portion of the first pillar 125a and a portion of the second pillar 125b. The portions of the first and second pillars 125a, 125b are arranged adjacent to each other. This arrangement results in the formation of parallel p-n-junctions extending in a vertical direction between the drift region 115 and the body region 120. The super junction region 125 can also be referred to as a p-n-junction region.

In this embodiment, a width of each of the first and second pillars 125a, 125b can be about 3.5 μm. A height of each of the first and second pillars 125a, 125b can be between about 3 μm and 6 μm. However, it will be appreciated that the first and second pillars are not limited to having the exemplary height and/or width disclosed herein.

The active region 105 comprises an n-type doped JFET region 130. The JFET region is arranged above the first pillar 125a. The JFET region 130 is arranged to extend from the first pillar to an upper surface of the body region 120. The body region 120 is arranged on either side of the JFET region 130.

The active region 105 comprises a gate conductive region 135. The gate conductive region 135 is located above the JFET region 130 and the body region 120. The gate conductive region 135 is used to control a conduction channel in the active region 105.

The active region 105 comprises a first insulation region 140a. The first insulation region 140a is arranged between the JFET region 130 and the gate conductive region 135. The first insulation region 140a can extend along the sides of the gate conductive region 135. The first insulation region can be referred to as a gate oxide region 140a.

The active region 105 comprises a second insulation region 140b. The second insulation region 140b is arranged on or over the gate conductive region 135 and the gate oxide region 140a. The second insulation region can also be referred to as an interlayer dielectric layer 140b.

The device 100 includes source contact regions, which in this example are n⁺ source contact regions 145. The n+source contact regions 145 are arranged on either side of the JFET region 130 and below the gate oxide region 140a. During operation, a conduction channel is formed between the n+source contact regions 145 and the drift region 115 by application of a positive voltage to the gate conductive region 135.

The body region 120 comprises a contact region, which in this example comprises p+contact regions 150. The p+contact regions 150 are formed on either side of the JFET region 130 and adjacent a respective n+source contact 145 region.

The device 100 comprises a source contact 155. The source contact 155 can comprise a conductive material, such as a metal material. The metal material can comprise aluminum, tungsten, titanium or a combination thereof. The source contact 155 is located on an upper surface of the device. For example, the source contact 155 can be arranged on or over the interlayer dielectric layer 140b. The source contact 155 can also be arranged to contact the n+source contact 145 regions and the p+contact regions 150.

In the embodiments shown in FIG. 1, a lateral extension or a width of the unit cell of the device 100 is about 7 μm. However, it will be appreciated that in other embodiments, the lateral extension or cell pitch can be more or less than 7 μm. The lateral extension or the width of the unit cell of the device can also be referred to as cell pitch.

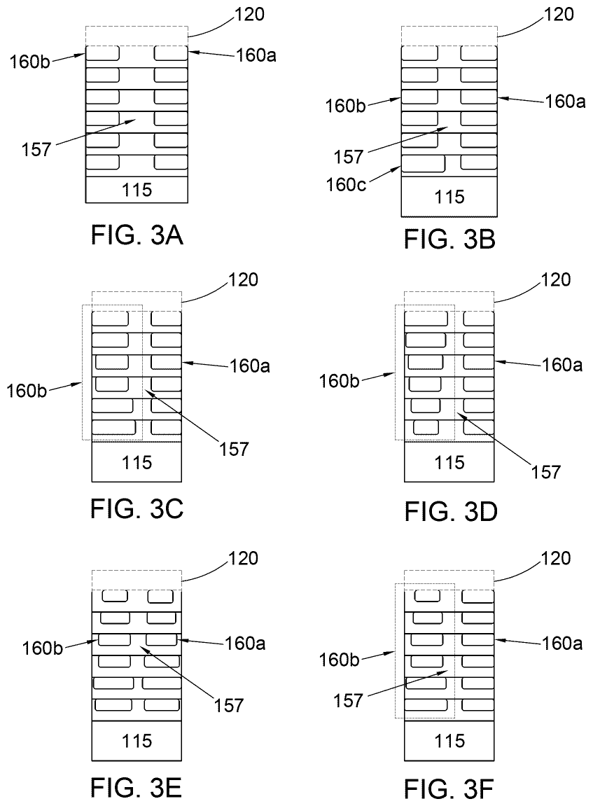

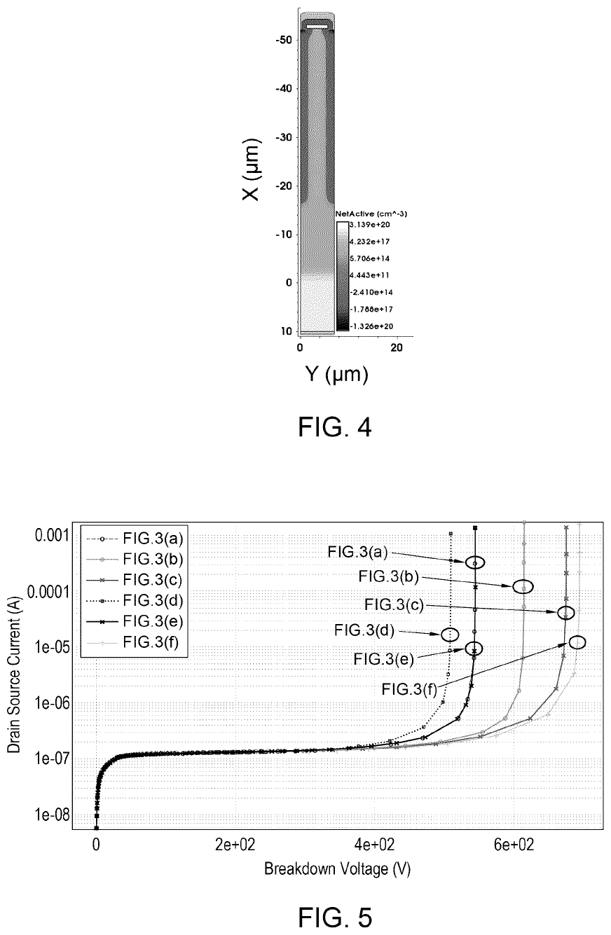

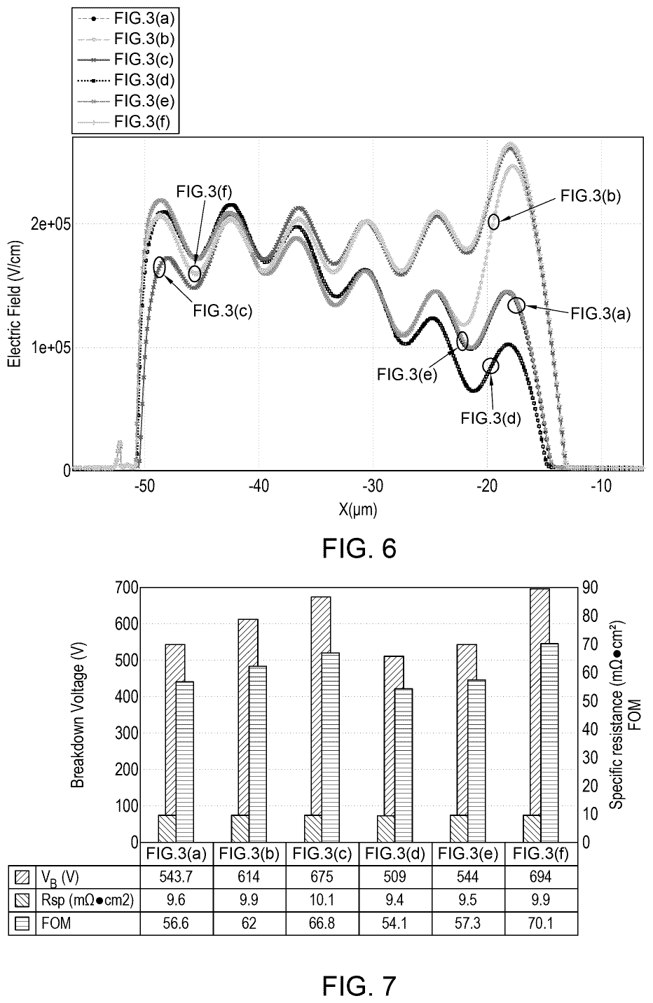

FIGS. 3A to 3F show schematically different exemplary distributions of dopant dosages that can be used to form the first and second pillars 125a, 125b. As will be described below in more detail, the first and second pillars 125a, 125b can be formed by implantation of an n-type dopant and p-type dopant, respectively, in a plurality of semiconductor layers, which are indicated in FIGS. 3A to 3F by reference numeral 157. The semiconductor layers 157 can also be referred to as epitaxial layers. Each of the semiconductor layers can have a thickness of about 6 μm. However, it will be appreciated that in other embodiments, a thickness of each semiconductor layer can be more or less than 6 μm.

The n-type dopant dosage is indicated by reference numeral 160a and the p-type dopant dosage is indicated by reference numeral 160b. For sake of clarity only the drift region 115 and the body region 120 are indicated in FIGS. 3A to 3F.

In the examples shown in FIGS. 3A to 3F, the first and second pillars 125a, 125b are formed from six semiconductor layers 157. However, it will be appreciated that in other embodiments, the first and second pillars can be formed from more or less than six semiconductor layers.

In the example shown in FIG. 3A, each of the semiconductor layers 157 is implanted with the same dosage of the p-type dopant and n-type dopant. For example, the p-type dopant 160b and the n-type dopant 160a implantation dosages can be about 1.1×10¹³ cm⁻².

As such, a doping concentration of each of the first and second pillars 125a, 125b is constant in a direction along each of the first and second pillars 125a, 125b from the drift region 115 to the body region 120. The terms “a direction along the first/second pillar” can be understood as encompassing the terms “a direction parallel to a longitudinal axis of the first/second pillar.” The direction along the first/second pillar can also be referred to as a vertical direction.

In the example shown In FIG. 3B, a p-type dopant dosage 160b of the semiconductor layer 157 adjacent the drift region 115 is higher relative to the p-type dopant of the remaining semiconductor layers 157. As such, a p-type dopant enrichment region 160c is formed in the second pillar 125b in proximity of the drift region 115. For example, the p-type dopant dosage of the enrichment region 160c is about 1.2×10¹³ cm⁻². The p-type dopant dosage of each of the remaining semiconductor layers 157 can be about 1.1×10¹³ cm⁻². The n-type dopant dosage 160a is the same for each semiconductor layer 157. For example, the n-type dopant dosage is about 1.1×10¹³ cm⁻² for each semiconductor layer 157. The doping concentration of the first pillar 125a is constant in the direction along the first pillar 125a from the drift region 115 to the body region 120.

In the example shown in FIG. 3C, the p-type dopant dosage 160b is varied across the semiconductor layers 157 in the direction from the drift region 115 to the body region 120. In this example, the p-type dopant dosage gradually decreases and then gradually increases in the direction from the drift region 115 to the body region 120. For example, the p-type dosage decreases from about 1.16×10¹³ cm⁻² to about 1.11×10¹³ cm⁻² and then increases from about 1.11×10¹³ cm⁻² to about 1.16×10¹³ cm⁻². The n-type dopant dosage 160a is the same for each semiconductor layer 157. For example, the n-type dopant dosage 160a is about 1.1×10¹³ cm⁻² for each semiconductor layer 157.

In the example shown in FIG. 3D, the p-type dopant dosage 160b is varied across the semiconductor layers 157 in the direction from the drift region 115 to the body region 120. In this example, the p-type dopant dosage 160b gradually increases in the direction from the drift region 115 to the body region 120. For example, the p-type dosage increases from about 1.07×10¹³ cm⁻² to about 1.12×10¹³ cm⁻². The n-type dopant dosage 160a is the same for each semiconductor layer 157. For example, the n-type dopant dosage 160a is about 1.1×10¹³ cm⁻² for each semiconductor layer 157.

In the example shown in FIG. 3E, the n-type dopant and p-type dopant dosages 160a, 160b are varied across the semiconductor layers 157 in the direction from the drift region 115 to the body region 120. In this example, the n-type dopant and p-type dopant dosages 160a, 160b simultaneously increase and then decrease in the direction from the drift region 115 to the body region 120. For example, the n-type dopant and p-type dopant dosages 160a, 160b simultaneously increase from about 1.1×10¹³ cm⁻² to about 1.16×10¹³ cm⁻² and then decreases from about to 1.05×10¹³ cm⁻².

FIG. 3F shows the n-type dopant and p-type dopant implanting dosages 160a, 160b according to an embodiment of the present disclosure. In FIG. 3F, the p-type dopant dosage 160b is varied across the semiconductor layers 157 in the direction from the drift region 115 to the body region 120. For example, the p-type dopant dosage 160b decreases in the direction from the drift region 115 to the body region 120. The p-type dopant dosage 160b can decrease from about 1.16×10¹³ cm⁻² to about 1.09×10¹³ cm⁻².

The n-type dopant dosage 160a is the same for each semiconductor layer 157. The n-type dopant dosage can be about 1.1×10¹³ cm⁻². It will be appreciated that in other embodiments, the n-type dopant dosage can be varied across the semiconductor layers and the p-type dopant dosage can be constant. In such other embodiments, the n-type dopant dosage can be increased, e.g. from about 1.05×10¹³ cm⁻² to 1.11×10¹³ cm⁻², in the direction from the drift region to the body region. In such other embodiments, the p-type dopant dosage can be the same for each semiconductor layer. For example, the p-type dopant dosage can be about 1.1×10¹³ cm⁻².

An implantation energy used for implanting the p-type dopant in the above examples can be between about 100 KeV and 850 KeV. An implantation energy used for implanting the n-type dopant in the above examples can be between about 140 KeV and 950 KeV.

FIG. 4 shows an active charge carrier concentration in an exemplary semiconductor power device that has been simulated using the distribution of the n-type dopant and p-type dopant implantation dosages described in relation to FIG. 3A. In other words, the n-type dopant and the p-type dopant concentrations of the first and second pillars, respectively, were assumed to be constant in the direction along the first and second pillars, respectively, from drift region to the body region, as described in relation to FIG. 3A.

FIG. 5 shows a graph of simulated drain source current curves over a breakdown voltage. The curves shown in FIG. 5 have been simulated for each of the n-type dopant and p-type dopant implantation dosage distributions described in relation to FIG. 3A to 3F, using the parameters of the device 100 described herein.

It can be seen from FIG. 5 that the highest breakdown voltage has been simulated for the device 100 with n-type dopant and p-type dopant implantation dosages as described in the FIG. 3F. In other words, by configuring the device 100 with a first pillar 125a having a constant n-type dopant concentration in the direction along the first pillar 125a from the drift region 115 to the body region 120 and at least a portion of a second pillar 125b having a p-type dopant concentration that decreases in the direction along the second a pillar 125b from the drift region 115 to the body region 120, a breakdown voltage of the device 100 can be increased. This in turn leads to an increase in a ratio of the breakdown voltage over a specific resistance of the device 100. This ratio can also be referred to the Figure of Merit (FOM).

Additionally, by configuring the device 100 with a first pillar 125a having a constant n-type dopant concentration in the direction along the first pillar 125a from the drift region 115 to the body region 120 and at least a portion of a second pillar 125b having a p-type dopant concentration that decreases in the direction along the second pillar 125b from the drift region 115 to the body region 120, an electric field at the top of the active region 105 can be decreased, leading to a more even distribution of the electric field in the active region 105 of the device 100. The effect of decreasing of the electric field at the top of the active region 105 can also be referred to as Reduced Surface Field (RESURF).

FIG. 6 shows a graph of electric field curves over a distance X between the drain contact and the source contact of the device. The curves shown in FIG. 6 have been simulated for each of the n-type dopant and p-type dopant implantation dosage distributions described in relation to FIG. 3A to 3F, using the parameters of the device 100 described herein. It can be seen from FIG. 6 that the electric field is more evenly distributed between the source contact 155 and the drain contact 110a for the device 100 with n-type dopant and p-type dopant implantation dosages as described in FIG. 3F compared to electric field curves simulated for the devices with the n-type dopant and p-type dopant implantation dosage distributions described in relation to FIG. 3A to 3E. In addition, it can be seen from FIG. 6 that the electric field is decreased in proximity of the source contact 155 for the device 100 with n-type dopant and p-type dopant implantation dosages as described in the FIG. 3F compared to electric field curves simulated for the devices with the n-type dopant and p-type dopant implantation dosage distributions described in relation to FIGS. 3A, 3B, 3D and 3E. Although the simulated electric field for the devices with the n-type dopant and p-type dopant implantation dosage distributions described in relation to FIG. 3C is decreased in proximity at the source contact, it is less even in the remainder of the active region compared to the electric field simulated for the device 100 with n-type dopant and p-type dopant implantation dosages as described in the FIG. 3F.

The electric field curves simulated for the devices with the n-type dopant and p-type dopant implantation dosage distributions as described in FIGS. 3A and 3E are very similar. It can be seen that the electric field simulated for these n-type dopant and p-type dopant implantation dosage distributions decreases towards the drain contact. The electric field curves simulated for the devices with the n-type dopant and p-type dopant implantation dosage distributions as described in FIGS. 3B and 3D are similar to those for the device with the n-type dopant and p-type dopant implantation dosage distributions as described in FIGS. 3A and 3E. However, the electric field curve simulated for the device with the n-type dopant and p-type dopant implantation dosage distribution as described in relation to FIG. 3B increases in proximity of the drain contact, whereas the electric field curve simulated for the device with the n-type dopant and p-type dopant implantation dosage distribution as described in relation to FIG. 3D is decreased in proximity of the drain contact compared to the electric field curves of the other devices. The electric field curve simulated for the device with the n-type dopant and p-type dopant implantation dosage distribution as described in relation to FIG. 3C is decreased in proximity of the source contact compared to the electric field curves of the other devices.

FIG. 7 shows a comparison of the breakdown voltage, specific resistance and Figure of Merit that has been simulated for each of the n-type dopant and p-type dopant implantation dosage distributions as described in FIGS. 3A to 3F, using the parameters of the device disclosed herein.

The specific resistance Rₛₚ is as follows:

$${R}_{sp} = 2 * {W}_{pitch} * \frac{{V}_{B}}{μ * {ε}_{S} * {E}_{C}^{2}} ,$$

where W_{pitch} is the width of the unit cell, V_{B} is the breakdown voltage, μ is the electron mobility, ε_{S} is the permittivity of silicon and E_{C} is the critical electric field. As described above the Figure of Merit corresponds to the ratio V_{B}/Rₛₚ.

From FIG. 7, it can be seen that the breakdown voltage increases from about 543.7 V for the device with the n-type dopant and p-type dopant implantation dosage distribution as described in FIG. 3A to 694 V for the device with the n-type dopant and p-type dopant implantation dosage distribution as described in FIG. 3F. The specific resistance increases from 9.6 mΩ·cm² for the device with the n-type dopant and p-type dopant implantation dosage distribution as described in relation to FIG. 3A to 9.9 mΩ·cm² for the device with the n-type dopant and p-type dopant implantation dosage distribution as described in relation to FIG. 3F. However, the Figure of Merit has increased from 56.6 for the device with the n-type dopant and p-type dopant implantation dosage distribution as described in relation to FIG. 3A to 70.1 for the device with the n-type dopant and p-type dopant implantation dosage distribution as described in relation to FIG. 3F.

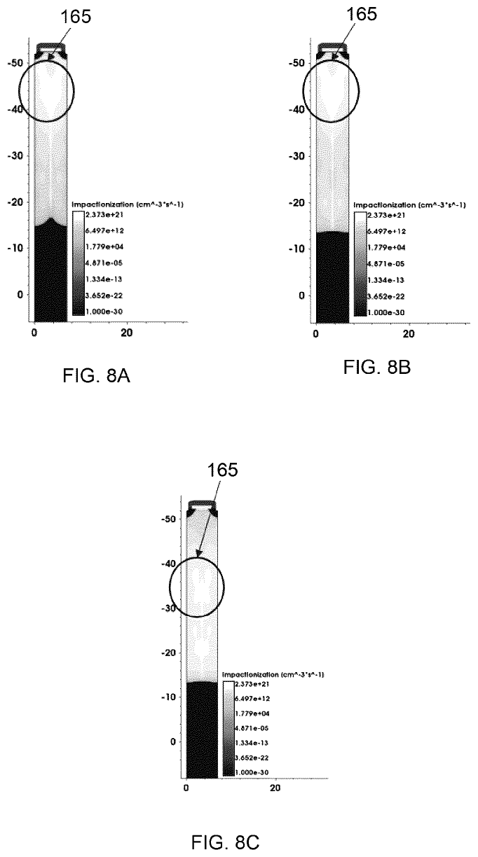

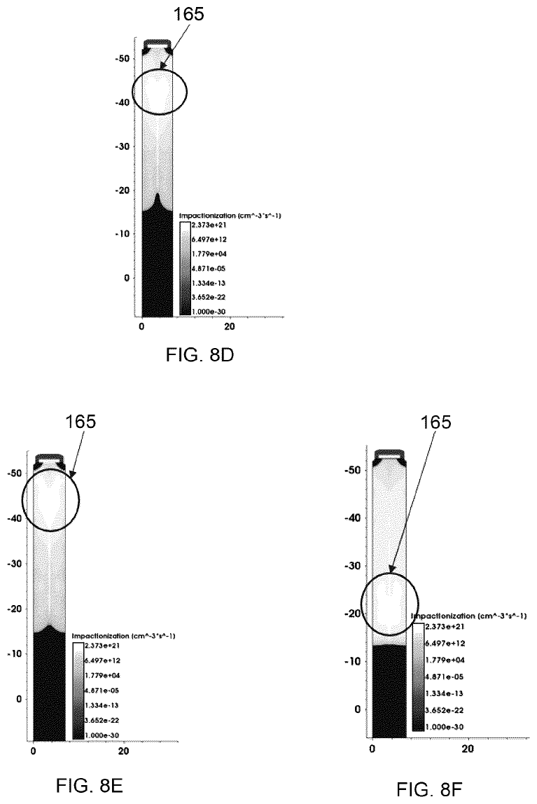

FIGS. 8A to 8F show simulations of impact ionization locations 165. The impact ionization locations 165 shown in FIGS. 8A to 8F have been simulated for each of the n-type dopant and p-type dopant implantation dosage distributions as described in relation FIGS. 3A to 3F, using the parameters of the device 100 described herein. The impact ionization location 165 can be considered as a location at which breakdown occurs. It can be seen from FIGS. 8A, 8B, 8D and 8E that for the corresponding devices with the n-type dopant and p-type dopant implantation dosage distributions as described in relation to FIGS. 3A, 3B, 3D and 3E, respectively, the simulated impact ionization location 165 is at or near the body region 120. For the device with the n-type dopant and p-type dopant implantation dosage distribution as described in relation to FIG. 3C, the impact ionization location 165 is near a center of the super junction region 125. For the device with the n-type dopant and p-type dopant implantation dosage distribution as described in FIG. 3F, the impact ionization location 165 is at the bottom of the super junction region 125. For example, for the device with the n-type dopant and p-type dopant implantation dosage distribution as described in FIG. 3F, the impact ionization location 165 is proximal to the drift region 115. This can result in an improved non-latch-up performance of the device 100 with the n-type dopant and p-type dopant implantation dosage distribution as described in FIG. 3F. Latch-up can be understood as a creation of a low-impedance path between regions of the device 100 that triggers turn-on of a parasitic n-p-n bipolar transistor structure between the source contact regions 145, the body region 120 and the first pillar 125 or the drain region 115. The improved latch-up performance can in turn result in a more even distribution of heat generated in the device 100 compared to the devices with the n-type dopant and p-type dopant implantation dosage distributions as described in relation to FIGS. 3A to 3E.

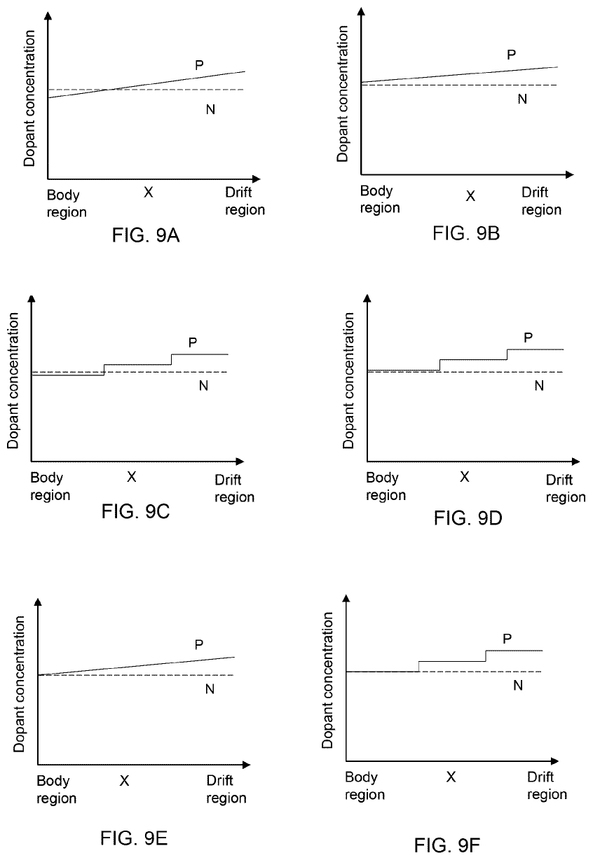

FIGS. 9A to 9F show exemplary n-type dopant and p-type dopant concentrations of the first and second pillars 125a, 125b, respectively, according to embodiments of the present disclosure. In the examples shown in FIGS. 9A to 9F, the concentration of the n-type dopant of the first pillar 125a is constant in the direction X along the first pillar 125a from the drift region 115 to the body region 120. The concentration of the p-type dopant of the second pillar decreases in the direction X along the second pillar 125b from the drift region 115 to the body region 120.

In some embodiments, the p-type dopant concentration of the second pillar 125b at or near the body region 120 is less than the n-type dopant concentration of the first pillar 125a, as shown in FIGS. 9A and 9C.

In some embodiments, the p-type dopant concentration of the second pillar 125b at or near the body region 120 is larger than the n-type dopant concentration of the first pillar 125a, as shown in FIGS. 9B and 9D.

In some embodiments, the p-type dopant concentration of the second pillar 125b at or near the body region 120 can be the same as the n-type dopant concentration of the first pillar 125a, as shown in FIGS. 9E and 9F.

In some embodiments, the p-type dopant concentration of the second pillar 125b decreases linearly in the direction X along the second pillar 125b from the drift region 115 to the body region 120, as shown in FIGS. 9A, 9B and E.

In some embodiments, the p-type dopant concentration of the second pillar 125b decreases stepwise in the direction X along the second pillar 125b from the drift region 115 to the body region 120, as shown in FIGS. 90, 9D and 9F. In the examples shown in FIGS. 9C, 9D and 9F, the p-type dopant concentration of the second pillar 125b decreases in three steps in the direction X along the second pillar 125b from the drift region 115 to the body region 120. However, it will be appreciated that in other embodiments, p-type dopant concentration can decrease in more than three steps or at least two steps in the direction along the second pillar from the drift region to the body region.

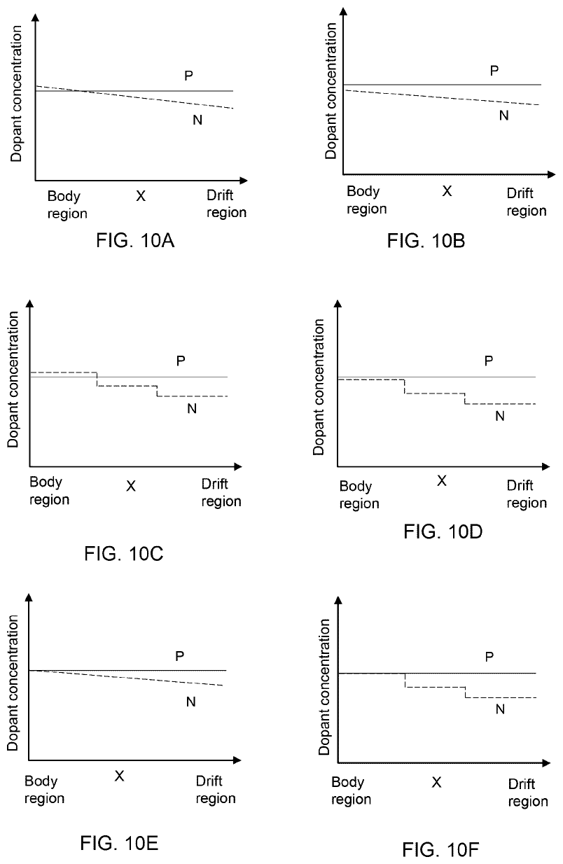

FIGS. 10A to 10F show exemplary n-type dopant and p-type dopant concentrations of the first and second pillars 125a, 125b, respectively, according to embodiments of the present disclosure. In the examples shown in FIGS. 10A to 10F, the concentration of the p-type dopant of the second pillar 125b is constant in the direction X along the second pillar 125b from the drift region 115 to the body region 120. The concentration of the n-type dopant of the first pillar 125a increases in the direction X along the first pillar 125a from the drift region 115 to the body region 120.

In some embodiments, the p-type dopant concentration of the second pillar 125b at or near the body region 120 is less than the n-type dopant concentration of the first pillar 125a, as shown in FIGS. 10A and 10C.

In some embodiments, the p-type dopant concentration of the second pillar 125b at or near the body region 120 is larger than the n-type dopant concentration of the first pillar 125a, as shown in FIGS. 10B and 10D.

In some embodiments, the p-type dopant concentration of the second pillar 125b at or near the body region 120 can be the same as the n-type dopant concentration of the first pillar 125a, as shown in FIGS. 10E and 10F.

In some embodiments, the n-type dopant concentration of the first pillar 125a increases linearly in the direction X along the first pillar 125a from the drift region 115 to the body region 120, as shown in FIGS. 10A, 10B and 10E.

In some embodiments, the n-type dopant concentration of the first pillar 125a increases stepwise in the direction X along the first pillar 125a from the drift region 115 to the body region 120, as shown in FIGS. 10C, 10D and 10F. In the examples shown in FIGS. 10C, 10D and 10F, the n-type dopant concentration of the first pillar 125a increases in three steps in the direction X along the first pillar 125a from the drift region 115 to the body region 120. However, it will be appreciated that in other embodiments, n-type dopant concentration can increase in more than three steps or at least two steps in the direction from the drift region to the body region.

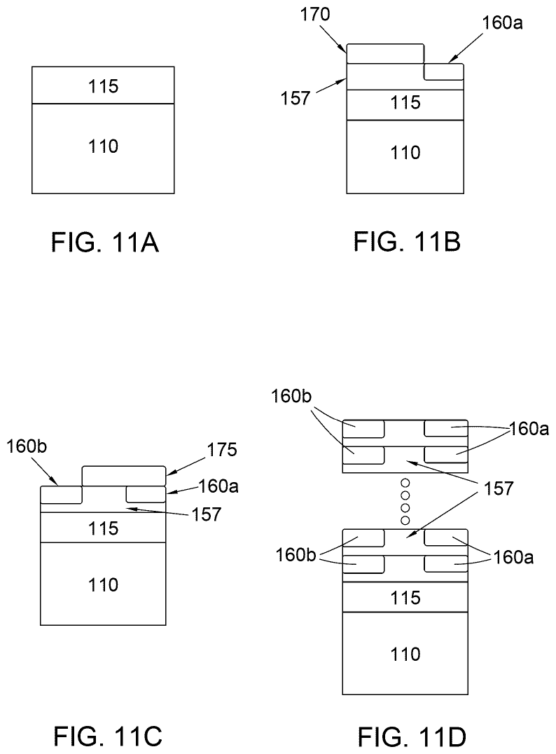

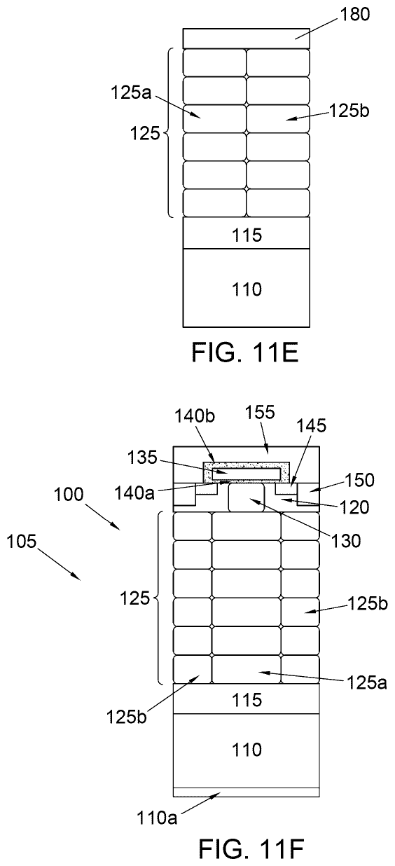

FIGS. 11A to 11F shows steps of a method of manufacturing an active region of a semiconductor power device according to an embodiment of the disclosure, such as the active region 105 of the device 100 described above. Many of the features are the same as those shown in FIGS. 1 and 2 and therefore carry the same reference numerals. It will be appreciated that the steps shown in FIGS. 11A to 11F can illustrate a subset of all the steps for manufacturing a device, and that the method can further include additional steps preceding or following the steps of FIGS. 11A to 11F. Whilst FIGS. 11A to 11F show steps in manufacturing an active area having one first pillar 125a and two second pillars 125b, it will be understood that the method can be used to manufacture an active region comprising more than one first pillar and more than two second pillars.

In step (a), the method comprises forming the drift region 115 on the substrate 110. The drift region 115 can be formed on the substrate 110 using a deposition process.

In steps (b) to (e), the method comprises forming the super junction region 125 on the drift region 115. Steps (b) to (c) can each be performed in turn a plurality of times. In the example shown in FIG. 11, the steps (b) and (c) are performed six times. However, it will be appreciated that these steps can be performed more or less than six times.

In step (b), the method comprises depositing a semiconductor layer 157 on or over the drift region 115. The semiconductor layer 157 can be deposited using a deposition process. The method comprises forming a first mask 170 on the semiconductor layer 157. The step of forming the first mask 170 on the semiconductor layer 157 can comprise depositing a layer of mask material, such as a layer of resist or photoresist material, on the semiconductor layer 157. The step of forming the first mask 170 on the semiconductor layer 157 can comprise patterning the layer of mask material. This can comprise exposing a part of the layer of mask material. The step of forming the first mask 170 on the semiconductor layer 157 can comprise developing the layer of mask material. A material removal process, such as etch process, can be used to remove the exposed part of the layer of mask material, thereby forming the first mask 170.

The first mask 170 exposes an upper surface of a first region of the semiconductor layer 157. The exposed upper surface of the first region of the semiconductor layer 157 can have a width of about 2.6 μm. The exposed upper surface of the first region of the semiconductor layer 157 can also be referred to as an opening of the first mask 170. It will be appreciated that in other embodiments, the width of the exposed upper surface of the first region of the semiconductor layer can be more or less than 2.6 μm.

The method comprises selectively doping the first region of the semiconductor layer 157 by implanting an n-type dopant. The n-type dopant can comprise phosphor, arsenic or another n-type dopant. The n-type dopant dosage is indicated in FIG. 11 by reference numeral 160a.

In step (c), the method comprises forming a second mask 175 on the semiconductor layer 157. The second mask 175 can be formed in the same manner as the first mask 170. The second mask 175 exposes an upper surface of a second region of the semiconductor layer 157. The second region of the semiconductor layer 157 is laterally spaced from the first region of the semiconductor layer 157. The exposed upper surface of the second region of the semiconductor layer 157 can have a width of about 2.6 μm. The exposed upper surface of the second region of the semiconductor layer 157 can also be referred to as an opening of the second mask 175. It will be appreciated that in other embodiments, the width of the exposed upper surface of the second region of the semiconductor layer can be more or less than 2.6 μm.

The method comprises selectively doping the second region of the semiconductor layer 157 by implanting a p-type dopant. The p-type dopant can comprise boron, boron difluoride or another p-type dopant. The p-type dopant dosage is indicated in FIG. 11 by reference numeral 160b.

The first and second regions of the semiconductor layer 157 can be implanted using an implantation process, such as vapor diffusion or another implantation process. An implantation energy used for implanting the p-type dopant can be between about 100 KeV and 850 KeV. An implantation energy used for implanting the n-type dopant in the above examples can be between about 140 KeV and 950 KeV. An implantation depth of the n-type and p-type dopants can be between about 0.5 μm and about 1.7 μm.

In step (d), the method comprises repeating steps (b) and (c). In this example, steps (b) and (c) are repeated six times. The number of repetitions of step (b) and (c) can be dependent on a required or desired breakdown voltage of the device 100. In the embodiments shown herein, the required or desired breakdown voltage is about 600 V. However, it will be appreciated that in other embodiments, the required or desired breakdown voltage of the device can be more or less than 600 V. In such other embodiments, steps (b) and (c) can be repeated more or less than six times.

Each time step (b) is performed, a subsequent semiconductor layer 157 is deposited on a previously deposited semiconductor layer 157.

Each time step (b) is performed, the first mask 170 exposes a same first region of the subsequent semiconductor layer 157 as in one or more previous repetitions of step (b). Each time step (c) is performed, the second mask 175 exposes a same second region of the subsequent semiconductor layer 157 as in one or more previous repetitions of step (c). The order of the n-type doing or p-type doing can be changed.

The semiconductor layers 157 are doped using a p-type dopant dosage that decreases from about 1.16×10¹³ cm⁻² to about 1.09×10¹³ cm⁻² in the direction from the drift region 115 to the body region 120. The n-type dopant dosage 160a is the same for each semiconductor layer 157. The n-type dopant dosage can be about 1.1×10¹³ cm⁻². It will be appreciated that in other embodiments, the n-type dopant dosage can be varied across the semiconductor layers and the p-type dopant dosage can be constant. In such other embodiments, the n-type dopant dosage can be increased, e.g. from about 1.05×10¹³ cm⁻² to 1.11×10¹³ cm⁻², in the direction from the drift region to the body region. In such other embodiments, the p-type dopant dosage can be the same for each semiconductor layer. For example, the p-type dopant dosage can be about 1.1×10¹³ cm⁻².

In step (e), the method can comprise forming the first and second pillars 125a, 125b. For example, the method can comprise using a diffusion or redistribution process to form the first and second pillars 125a, 125b. The diffusion or redistribution process can comprise a drive-in process to further diffuse or redistribute the dopants, thereby forming the first and second pillars 125a, 125b. For example, the diffusion or redistribution process can be used to connect the first and second pillars 125a, 125b with each other.

A diffusion length of the n-type and p-type dopants during the initial vapor diffusion is generally less than a diffusion length of the n-type and p-type dopants during the drive-in process. Therefore, the drive-in process causes the n-type and p-type dopants to diffuse further into the semiconductor layers 157. During the drive-in process a temperature of the substrate 110, the drift region 115 and the semiconductor layers 157 is increased, e.g. to about 1125° C. for about 10 hours. The drive-in process causes the n-type and p-type dopants on the surface of the semiconductor layers 157 to be diffused further into the semiconductor layers 157, thereby forming the first and second pillars 125a, 125b. This in turn results in the formation of the super junction region 125.

In step (e), the method comprises depositing a further semiconductor layer 180 on the super junction region 125, e.g. using a deposition process. The further semiconductor layer 180 can have a thickness of about 2 μm. However, it will be appreciated that in other embodiments, the further semiconductor layer can he have a thickness of more or less than 2 μm. The further semiconductor layer 180 can also be referred to as a cap layer.

In step (f), the method comprises forming a third mask on the further semiconductor layer 180. The third mask exposes a region of the further semiconductor layer 180 above the first pillar 125a. The third mask can be formed in the same manner as the first and second masks 170, 175 described above.

In step (f), the method comprises forming the JFET region 130. The JFET region 130 can be formed by doping the exposed region of the further semiconductor layer 180 with an n-type dopant, e.g. using the implantation process mentioned above. The n-type dopant can comprise one or more of the exemplary n-type dopants mentioned above.

In step (f), the method further comprises forming the gate oxide region 140a above the JFET region 130. The gate oxide region 140a can comprise a thin oxide layer, such as silicon dioxide, that can be deposited or thermally grown.

In step (f), the method further comprises forming the gate conductive region 135. The method comprises depositing a layer of conductive material on the gate oxide region 140a and over the JFET region 130, e.g. using a deposition process. The conductive material can comprise a doped semiconductor material, such as doped polysilicon. A material removal process, such as a dry-etch or wet-etch process, can be used to form the gate conductive region 135. For example, the layer of conductive material can be etched using a mask so that this layer extends over the JFET region 130 to the source contact regions 145.

In step (f), the method further comprises forming the body region 120. For example, a p-type dopant can be implanted on an upper surface of the further semiconductor layer 180 so that the p-type body region 120 is formed on either side of the JFET region 130. The p-type dopant can be implanted using a blank implantation process. Subsequent to the implantation of the p-type dopant, the diffusion or redistribution process, comprising the drive-in process, is performed to further diffuse or redistribute the p-type dopants in the body region 120. During the drive-in process a temperature of the substrate 110, the drift region 115, super junction region 125 and further semiconductor layer 180 is increased, e.g. to about 1125° C. for about 100 minutes. The drive-in process causes the p-type dopant on the surface of the further semiconductor layer 180 to be diffused further into the further semiconductor layer 180, thereby forming the body region 120.

In step (f), the method further comprises forming the source contact regions 145. For example, an n-type dopant can be implanted on either side of the body region 120 to form the source contact regions 145. An n-type dopant concentration of each of the source contact regions 145 can be larger than 5×10¹⁸ cm 3. The n-type dopant can comprise one or more of the exemplary n-type dopants mentioned above. The n-type dopant can be implanted using a blank implantation process.

In step (f), the method further comprises forming the interlayer dielectric (ILD) layer 140b. For example, the interlayer dielectric layer 140b can be formed by depositing a layer of insulating material on or over the gate conductive region 135, e.g. using a deposition process. The layer of insulating material can comprise an oxide material, such as TEOS (tetraethyl orthosilicate). The interlayer dielectric layer 140b can also be deposited on or over the gate oxide region 140a.

In step (f), the method further comprises forming the p+contact regions 150. The method comprises forming contact openings or recesses, e.g. using a material removal process, e.g. on either side of the gate conductive region 135. For example, the contact openings or recesses can be formed by etching through the interlayer dielectric layer 140b and the gate oxide region 140a. A p-type dopant can be implanted below each contact opening or recess to form the p+contact regions 150. A p-type dopant concentration of the p+contact region 150 can be larger than 5×10¹⁸ cm⁻³. The p-type dopant can comprise one or more of the exemplary p-type dopants mentioned above. The p-type dopant can be implanted using a blank implantation process.

In step (f), the method further comprises forming the source contact 155. For example, the source contact 155 can be formed by depositing a layer of conductive material into each contact opening or recess and on or over the interlayer dielectric layer 140b, e.g. so that the source contact 155 contacts the source contact regions 145 and the p+contact regions 150.

In step (f), the method further comprises forming the drain contact 110a. For example, the drain contact 110a can be formed by grinding or planarizing a lower surface of the substrate 110 and depositing a layer of conductive material thereon. The layer of conductive material can be deposited on the lower surface of the substrate 110 using a deposition process, such as an evaporation process.

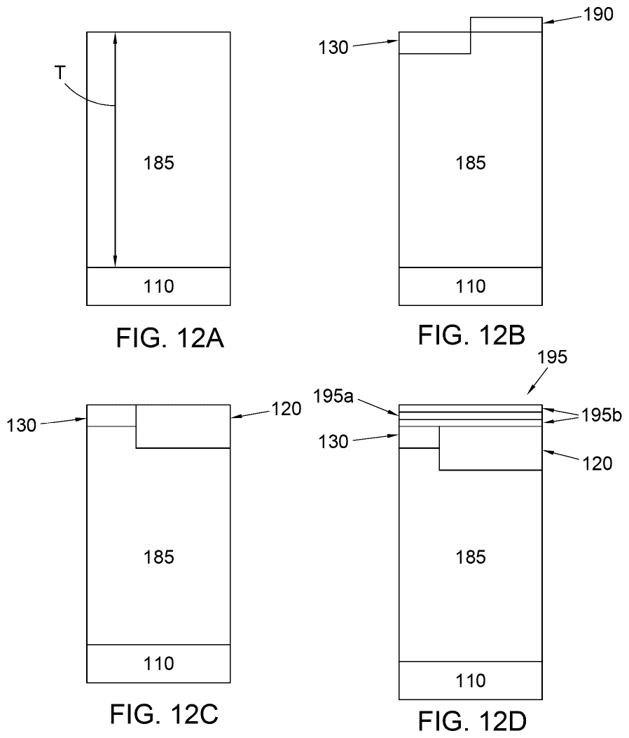

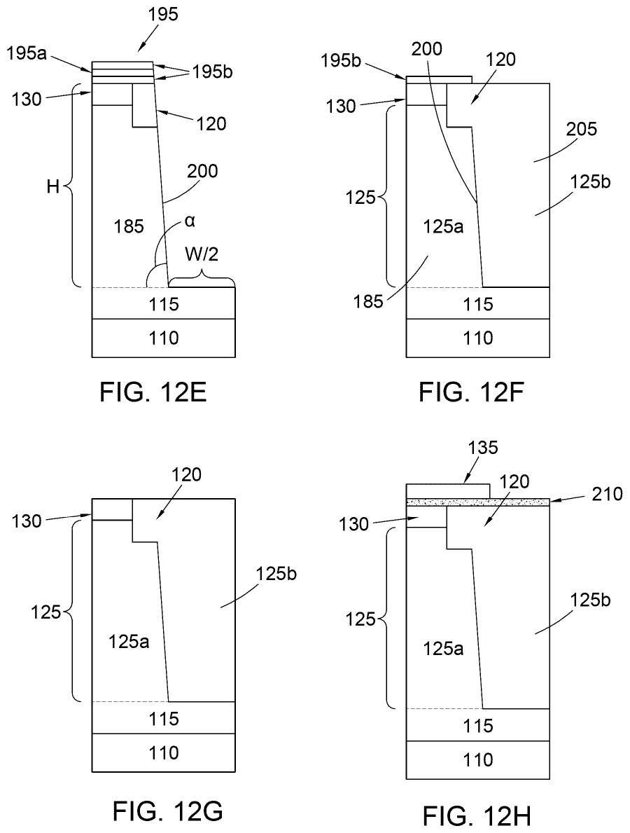

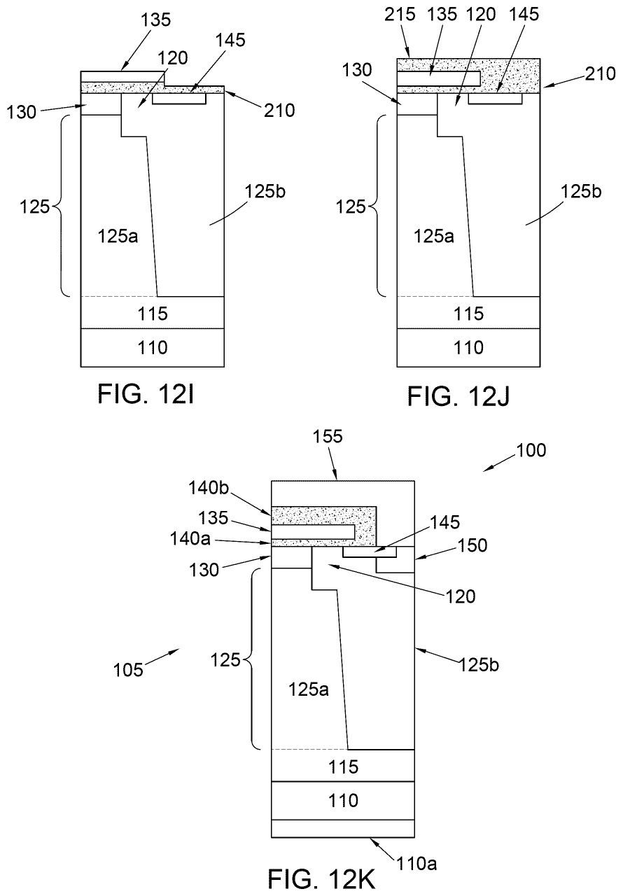

FIGS. 12A to 12K shows steps of another method of manufacturing an active region of a semiconductor power device according to an embodiment of the disclosure, such as the active region 105 of the device 100 described above. Many of the features are the same as those shown in FIGS. 1 and 2 and therefore carry the same reference numerals. It will be appreciated that the steps shown in FIGS. 12A to 12K can illustrate a subset of all the steps for manufacturing a device, and that the method can further include additional steps preceding or following the steps of FIGS. 12A to 12K. Whilst FIGS. 12A to 12K show steps in manufacturing an active area having two first pillars 125a and one second pillar 125b, it will be understood that the method can be used to manufacture an active region comprising more than two first pillars and more than one second pillar. FIGS. 12A to 12K show the formation of a half of a unit cell of the device 100. However, it will be appreciated that any of the steps and/or features described below can also be applied to the formation of a unit cell of the device 100 or more than one unit cell of the device 100.

One or more of steps of the method described below in relation to FIGS. 12A to 12K are the same or similar to one or more steps of the method described above in relation to FIGS. 11A to 11F. As such, one or more features of the method described above in relation to FIGS. 11A to 11F can also apply to the method described below in relation to FIGS. 12A to 12K.

In step (a), the method comprises forming a semiconductor region 185. The semiconductor region 185 can be formed using a deposition process. In this embodiment, the semiconductor region 185 comprises an n-type doped semiconductor material, such as n-type doped silicon.

The semiconductor region 185 includes one or more epitaxial layers that have been formed on the substrate 110. A thickness T of the semiconductor region 185 can be about 50 μm. The thickness of the semiconductor region 185 can be dependent on the required or desired breakdown voltage of the device 100. In the embodiments shown herein the required or desired breakdown voltage is about 600 V. However, it will be appreciated that in other embodiments, the required or desired breakdown voltage of the device can be more or less than 600 V. In such other embodiments, the thickness of the semiconductor region can be more or less than 50 μm.

In step (b), the method comprises forming the JFET region 130. The step of forming the JFET region 130 can comprise forming a fourth mask 190 on the semiconductor region 185. The fourth mask exposes an upper surface of a first region of the semiconductor region 185. The fourth mask can be formed in the same manner as the first and second masks 170, 175 described above.

The JFET region 130 can be formed by doping the first region of the semiconductor region 185 with an n-type dopant, e.g. using the implantation process mentioned above. The n-type dopant can comprise one or more of the exemplary n-type dopants mentioned above.

In step (c), the method comprises forming the body region 120. The step of forming the body region 120 can comprise forming a fifth mask on the semiconductor region 185. The fifth mask exposes an upper surface of a second region of the semiconductor region 185. The second region of the semiconductor region 185 is located adjacent the JFET region 130. The fifth mask can be formed in the same manner as the first and second masks 170, 175 described above.

The body region 120 can be formed by doping the second region of the semiconductor region 185 with a p-type dopant. The p-type dopant can be implanted using a blank implantation process. Subsequent to the implantation of the p-type dopant, the diffusion or redistribution process, comprising the drive-in process, is performed to further diffuse or redistribute the p-type dopants in the body region 120. During the drive-in process a temperature of the substrate 110 and the semiconductor region 185 is increased, e.g. to about 1125° C. for about 100 minutes. The drive-in process causes the p-type dopant on the surface of the semiconductor region 185 to be diffused further into the semiconductor region 185, thereby forming the body region 120.

In step (d), the method comprises depositing a layer of mask material 195 on the upper surface of the semiconductor region 185, e.g. over the JFET region 130 and the body region 120. The layer of mask material 195 comprises a stack of a layer of nitride material 195a sandwiched between two layers of oxide material 195b. The nitride material can comprise silicon nitride, such as such as Si₃N₄ or the like. The oxide material can comprise TEOS (tetraethyl orthosilicate) or the like. The layer of mask material 195 can be patterned, e.g. using a material removal process, such as a dry-etch process or a wet-etch process.

In step (e), the method comprises forming a trench 200 in the semiconductor region 185. The trench 200 is formed so that it extends through the body region 120 into semiconductor region 185. The trench 200 extends into the semiconductor region 185 in a vertical direction (e.g. a direction that is perpendicular to the substrate 110). The trench 200 is in contact with the body region 120. The trench 200 can be formed using a material removal process, such as a dry-etch process. The patterned layer of mask material can act as a hard mask or resists layer to define the trench 200 during the material removal process.

The trench 200 can comprise a height H of about 35 μm. The trench 200 can comprise a width of about 5 μm. As FIG. 12E shows half of the unit cell of the device, the width of the trench 200 is indicated by reference numeral W/2. The sidewalls of the trench 200 can be formed at an angle α relative to a surface of the substrate 110. The angle α can be between about 80 degrees and about 90 degrees, such as about 88 degrees. A portion of the semiconductor region 185 below the trench 200 can define the drift region 115. The trench 200 is also in contact with the drift region 115. It will be appreciated that in other embodiments, a height and/or width of trench can be different from the exemplary height and/or width disclosed herein.

In step (f), e.g. subsequent to the formation of the trench 200, a portion of the layer of mask material 195 can be removed, e.g. using a material removal process, such as a wet-etch process. In this embodiment, the upper of the two layers of oxide material 195b and the layer of nitride material 195a are removed. The lower of two layers of oxide material 195b remains on the upper surface of the semiconductor region 185, e.g. on the body region 120 and the JFET region 130.

In step (f), the method further comprises filling the trench 200 with a p-type semiconductor material 205, such as p-type doped silicon. The trench 200 can be filled with the semiconductor material 205 using a deposition process. In this embodiment, the semiconductor material 205 can be doped so that a doping concentration of the semiconductor material 205 in the trench 200 decreases in a direction along the trench 200 from the drift region 115 to the body region 120. For example, the p-type doping concentration of the semiconductor material 205 in the trench 200 can decrease from about 7.35×10¹⁵ cm⁻³ to 6.9×10¹⁵ cm⁻³ in the direction along the trench 200 from the drift region 115 to the body region 120. The direction along the trench 200 can also be understood as a vertical direction, e.g. a direction parallel to a longitudinal axis of the trench 200. In this embodiment, the trench 200 forms the second pillar 125b. A portion of the semiconductor region 185 that is located adjacent to the trench 200 forms the first pillar 125a. A doping concentration of the first pillar 125a is constant in the direction along the first pillar from the drift region 115 to the body region 120. For example, an n-type doping concentration of the first pillar 125a can be about 7×10¹⁵ cm⁻³. However, it will be appreciated that in other embodiments, a doping concentration of the first pillar can increases in the direction along the first pillar from the drift region to the body region and a doping concentration of the second pillar or portion thereof can be constant in the direction along the second pillar from the drift region to the body region. In such other embodiments, the p-type doping concentration of the second pillar or portion thereof can be about 7×10¹⁵ cm⁻³. The n-type doping concentration of the first pillar can increase from about 6.65×10¹⁵ cm⁻³ to about 7.2×10¹⁵ cm⁻³ in the direction along the first pillar from the drift region 115 to the body region 120.

In this embodiment, the body region 120 is located on a part of the super junction region 125, e.g. on at least a part of the first pillar 125a. As such, the super junction region 125 can be considered as being arranged at least partially between the drift region 115 and the body region 120.

In step (f), the method further comprises removing a portion of the semiconductor material 205 that extends beyond the body region 120 and the JFET region 130, e.g. using a material removal process, such as a dry-etch process or chemical-mechanical polishing process.

In step (g), the method comprises removing a remainder of the layer of mask material 195, e.g. the lower of two layers of oxide material 195b. The remainder of the layer of mask material 195 can be removed using a material removal process, such as a wet-etch process. A sacrificial layer of oxide material can be deposited on the JFET region 130, the body region 120 and the second pillar 125b. The sacrificial layer of oxide material can subsequently be removed.

In step (h), the method comprises depositing a layer of oxide material 210, such as silicon dioxide, on the JFET region 130, the body region 120 and the second pillar 125b.

In step (h), the method further comprises forming the gate conductive region 135. The method comprises depositing a layer of conductive material on the layer of oxide material 210. The conductive material can comprise a doped semiconductor material, such as doped polysilicon. A material removal process, such as a dry-etch or wet-etch process, can be used to form the gate conductive region 135. For example, the layer of conductive material can be etched using a mask so that this layer extends over the JFET region 130 and the body region 120. A portion of the layer of oxide material 210 that is located over the second pillar 125b is exposed.

In step (i), the method comprises partially removing the exposed portion of the layer of oxide material 210 using a material removal process, such as a dry-etch or wet-etch process.

In step (i), the method further comprises forming the source contact region 145. For example, an n-type dopant is implanted in a region of the second pillar 125b adjacent to the body region 120 to form the source contact regions 145. The region of the second pillar 125b that is implanted with the n-type dopant is located below the layer of oxide material 210 and extends from the exposed portion of the layer of oxide material 210 to the gate conductive region 135. A sixth mask exposes the region of the second pillar 125b to be implanted.

An n-type dopant concentration of the source contact region 145 can be larger than 5×10¹⁸ cm⁻³. The n-type dopant can comprise one or more of the exemplary n-type dopants mentioned above. The n-type dopant can be implanted using a blank implantation process. Subsequent to the implantation of the n-type dopant, the diffusion or redistribution process, comprising the drive-in process, is performed to further diffuse or redistribute the n-type dopants in the region of the second pillar 125b. During the drive-in process a temperature of at least the second pillar 125b is increased, e.g. to about 1000° C. for about 30 minutes. The drive-in process causes the n-type dopant on the surface of the region of the second pillar 125b to be diffused further into this region, thereby forming the source contact region 145.

In step (j), the method comprises forming the interlayer dielectric layer 140b. For example, the interlayer dielectric layer 140b can be formed by depositing a layer of insulating material on or over the gate conductive region 135 and the exposed portion of the layer of oxide material 210, e.g. using a deposition process. The layer of insulating material can comprise an oxide material, such as TEOS (tetraethyl orthosilicate).

In step (k), the method further comprises forming the p+contact region 150. The method comprises forming an opening or recess, e.g. using a material removal process. The opening or recess is laterally spaced from the gate conductive region 135. The contact opening or recess can be formed by etching through the interlayer dielectric layer 140b and the layer of oxide material 210. The remainder of the layer of oxide material 210 forms the gate oxide region 140a.

A p-type dopant can be implanted below the contact opening or recess to form the p+contact region 150. A p-type dopant concentration of the p+contact region 150 can be larger than 5×10¹⁸ cm⁻³. The p-type dopant can comprise one or more of the exemplary p-type dopants mentioned above. The p-type dopant can be implanted using a blank implantation process.

In step (k), the method further comprises forming the source contact 155. For example, the source contact 155 can be formed by depositing a layer of conductive material into the contact opening or recess and on or over the interlayer dielectric layer 140b, e.g. so that the source contact 155 contacts the source contact region 145 and the p+contact region 150.

In step (k), the method further comprises forming the drain contact 110a. For example, the drain contact 110a can be formed by grinding or planarizing a lower surface of the substrate 110 and depositing a layer of conductive material thereon. The layer of conductive material can be deposited on the lower surface of the substrate 110 using a deposition process, such as an evaporation process.

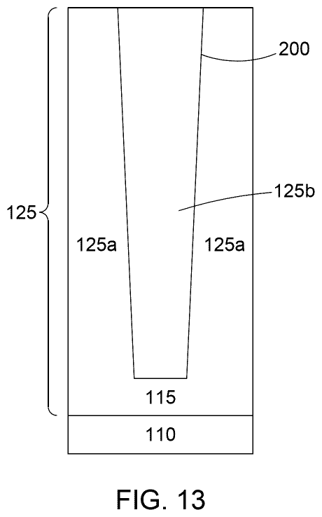

FIG. 13 shows schematically a cross-section of a super junction region 125 that has been formed using one or more steps of the method described in relation to FIGS. 12A to 12K. In the embodiment shown in FIG. 13, the super junction region 125 comprises a second pillar 125b that is arranged between two portions of two first pillars 125a. However, it will be appreciated that the device 100 can more than one second pillar 125b and more than two first pillars 125a, as mentioned above.

The deposition process described above can comprise a chemical vapor deposition process, sputtering process or another deposition process.

The dry-etch process mentioned above can include a reactive ion etch process or another dry-etch process.

It will be appreciated that the term “constant” used herein encompasses the terms “substantially constant.”

It will be appreciated that the terms “the same” used herein encompasses the terms “substantially the same.”

It will be appreciated that the term “width” used herein encompasses a size, dimension or extension of a part or feature in a lateral direction, e.g. a direction parallel to the y-axis in FIG. 4.

It will be appreciated that the term “thickness” or “height” used herein encompasses a size, dimension or extension of a part or feature in a longitudinal or vertical direction, e.g. a direction parallel to the x-axis in FIG. 4 and/or a direction perpendicular to the lateral direction.

The skilled person will understand that in the preceding description and appended claims, positional terms such as ‘above’, ‘overlap’, ‘under’, ‘lateral, etc. are made with reference to conceptual illustrations of an apparatus, such as those showing standard cross-sectional perspectives and those shown in the appended drawings. These terms are used for ease of reference but are not intended to be of limiting nature. These terms are therefore to be understood as referring to a device when in an orientation as shown in the accompanying drawings.

It will be appreciated that all doping polarities mentioned above could be reversed, the resulting devices still being in accordance with embodiments of the present disclosure.

Although the above description refers to the device comprising a MOSFET, it will be appreciated that in other embodiments the device can comprise an insulated-gate bipolar transistor (IGBT). Any of the above-mentioned features can also apply to the IGBT. In such other embodiments, the terms “drain region” can be replaced with the terms “collector region” and the term “source”, as used above, can be replaced with the term “emitter”.

In this document, dimensions are provided merely as indicative examples, and are not intended to be limiting.

It will be appreciated that FIGS. 1 to 3F, 11A to 11F, 12A to 12K and 13 are schematic drawings of some embodiments of the disclosure are not necessarily to scale.

Although specific embodiments have been described above, the claims are not limited to those embodiments. Those skilled in the art will be able to make modifications and alternatives in view of the disclosure, which are contemplated as falling within the scope of the appended claims. Each feature disclosed can be incorporated in any of the described embodiments, alone or in an appropriate combination with other features disclosed herein.

### REFERENCE NUMERALS

100 Device
105 Active region
110 Substrate
110a Drain contact
115 Drift region
120 Body region
125 Super junction region
125a First pillar
125b Second pillar
130 JFET region
135 Gate conductive region
140a Gate oxide region
140b Interlayer dielectric layer
145 n⁺source contact region
150 p⁺contact region 150
155 Source contact
155 Source contact
157 Semiconductor layer
160a n-type dopant dosage
160b p-type dopant dosage
160c Enrichment region
165 Impact ionization location
170 First mask
175 second mask
180 Further semiconductor layer
185 Semiconductor region
190 Fourth mask
195 Layer of mask material
195a Layer of nitride material
195b Layer of oxide material
200 Trench
205 p-type semiconductor material
210 Layer of oxide material
H Height of trench
W Width of trench
α Angle of sidewall of trench
T thickness of semiconductor region

What is claimed is:

1. A semiconductor power device comprising an active region, the active region comprising:
a drift region of a first conductivity type;
a body region of a second conductivity type, wherein the second conductivity type is opposite to the first conductivity type; and
a super junction region arranged at least partially between the drift region and the body region,
wherein the super junction region comprises a first pillar of the first conductivity type, and at least a portion of a second pillar of the second conductivity type,
wherein the first pillar is arranged adjacent to the portion of the second pillar,
wherein: the first pillar has a doping concentration that is constant in a direction along the first pillar from the drift region to the body region and a doping concentration of the portion of the second pillar decreases in a direction along the portion of the second pillar from the drift region to the body region; or the first pillar has a doping concentration that increases in the direction along the first pillar from the drift region to the body region and the doping concentration of the portion of the second pillar is constant in the direction along the portion of the second pillar from the drift region to the body region.

2. The semiconductor power device according to claim 1, wherein the doping concentration of the portion of the second pillar decreases linearly in the direction along the portion of the second pillar from the drift region to the body region; or wherein the doping concentration of the first pillar increases linearly in the direction along the first pillar from the drift region to the body region.

3. The semiconductor power device according to claim 1, wherein the doping concentration of the portion of the second pillar decreases stepwise in the direction along the portion of the second pillar from the drift region to the body region; or the doping concentration of the first pillar increases stepwise in the direction along the first pillar from the drift region to the body region.

4. The semiconductor power device according to claim 3, wherein the doping concentration of the portion of the second pillar decreases in two or more steps, or the doping concentration of the first pillar increases in two or more steps.

5. The semiconductor power device according to claim 1, wherein the doping concentration of the first pillar at or near the body region is larger, smaller, or the same as the doping concentration of the portion of the second pillar at or near the body region.

6. A semiconductor power device according to claim 1, wherein the super junction region comprises a plurality of first pillars and a plurality of second pillars alternately arranged with each other.

7. The semiconductor power device according to claim 6, wherein each of the plurality of first pillars is arranged adjacent to at least one of the plurality of second pillars.

8. The semiconductor power device according to claim 1, wherein the semiconductor power device comprises a metal-oxide-semiconductor field-effect transistor (MOSFET) or an insulated-gate bipolar transistor (IGBT).

9. A method of manufacturing an active region of a semiconductor power device, the method comprising:
forming a drift region of a first conductivity type on a substrate;
forming a super junction region on the drift region, the super junction region comprising: a first pillar of the first conductivity type, at least a portion of a second pillar of the second conductivity type,
wherein the first pillar is arranged adjacent to the portion of the second pillar,
wherein the first pillar has a doping concentration that is constant in a direction along the first pillar from the drift region to a body region and a doping concentration of the portion of the second pillar decreases in a direction along the portion of the second pillar from the drift region to the body region, or the first pillar has a doping concentration that increases in the direction along the first pillar from the drift region to the body region and the doping concentration of the portion of the second pillar is constant in the direction along the portion of the second pillar from the drift region to the body region; and
forming a body region of a second conductivity type on at least a part of the super junction region.

10. The method according to claim 9, wherein forming the super junction region comprises: performing each of the following steps (i) to (v) one or more times:
(i) depositing a semiconductor layer on or over the drift region;
(ii) forming a first mask on the semiconductor layer, the first mask exposing an upper surface of a first region of the semiconductor layer;
(iii) selectively doping the first region of the semiconductor layer to form a first region of a first conductivity type;
(iv) forming a second mask on the semiconductor layer, the second mask exposing an upper surface of a second region of the semiconductor layer, the second region of the semiconductor layer being laterally spaced from the first region of the semiconductor layer; and
(v) selectively doping the second region of the semiconductor layer to form a second region of a second conductivity type.

11. The method according to claim 10, further comprising:
in a first iteration, depositing the semiconductor layer on the drift region; and
in one or more subsequent iterations, depositing a subsequent semiconductor layer on a previously deposited semiconductor layer.

12. The method according to claim 11, wherein when at least one subsequent iteration has been performed:
a doping concentration of each first region of the first conductivity type is the same; and
a doping concentration of a second region of the second conductivity type formed in the at least one subsequent iteration is decreased relative to a doping concentration of a second region of the second conductivity type formed in a previous iteration.

13. The method according to claim 11, wherein, when at least one subsequent iteration has been performed,
a doping concentration of each second region of the second conductivity type is the same; and
a doping concentration of a first region of the first conductivity type formed in the at least one subsequent iteration is increased relative to a doping concentration of a first region of the first conductivity type formed in a previous iteration.

14. The method according to claim 9, further comprising using a diffusion or redistribution process to form the first pillar and at least the portion of the second pillar.

15. The method according to claim 9, wherein forming the super junction region further comprises:
forming a trench in a semiconductor region of a first conductivity type, wherein a portion of the semiconductor region that is located adjacent to the trench forms the first pillar; and
filling the trench with a semiconductor material of a second conductivity type to form at least the portion of the second pillar.

16. A method of manufacturing a semiconductor power device comprising:
manufacturing an active region of the semiconductor power device according to claim 9.

17. A method of manufacturing a semiconductor power device comprising:
manufacturing an active region of the semiconductor power device according to claim 10.

18. A method of manufacturing a semiconductor power device comprising:
manufacturing an active region of the semiconductor power device according to claim 11.

19. A method of manufacturing a semiconductor power device comprising:
manufacturing an active region of the semiconductor power device according to claim 12.

20. A method of manufacturing a semiconductor power device comprising:
manufacturing an active region of the semiconductor power device according to claim 13.
